(19) United States
(12) Patent Application Publication
(10) Pub. No.: US 2026/0190668 A1
(43) Pub. Date: Jul. 2, 2026

(54) DISPLAY DEVICE AND METHOD OF FABRICATING THE SAME

(71) Applicant: LG Display Co., Ltd., Seoul (KR)

(72) Inventors: Man-Ki JI, Paju-si (KR); Sung-Woo LEE, Paju-si (KR); Jin-Woo PARK, Paju-si (KR); Kyeong-Seob KWON, Paju-si (KR)

(73) Assignee: LG Display Co., Ltd., Seoul (KR)

(21) Appl. No.: 19/395,982

(22) Filed: Nov. 20, 2025

(30) Foreign Application Priority Data
Dec. 26, 2024 (KR) 10-2024-0196879

(51) Int. Cl. H10K 59/124; H10K 59/12; H10K 59/131

(52) U.S. Cl. CPC H10K 59/124; H10K 59/1201; H10K 59/131

(57) ABSTRACT

The disclosure relates to a display device and a method of fabricating the same. A display device comprises a substrate including a display area and a non-display area outside the display area; a light emitting element in a pixel in the display area; a trimming hole in an edge of the non-display area; a crack detection line disposed between the trimming hole and the display area and surrounding the display area; and a bridge pattern at least in the trimming hole.

### CROSS-REFERENCE TO RELATED APPLICATIONS

The present application claims the benefit of Korean Patent Application No. 10-2024-0196879 filed in the Republic of Korea on December 26, 2024, which is hereby incorporated by reference in its entirety.

### BACKGROUND

### TECHNICAL FIELD

The present disclosure relates to a display device (e.g., a display apparatus) and a method of fabricating the same, and more specifically, to a display device being capable of being simply assembled into a set and a method of fabricating the same.

### DESCRIPTION OF THE RELATED ART

As information technology develops, various types of small and thin display devices such as a liquid crystal display device, an organic light emitting display device, a plasma display device, and micro-LED display device, are introduced. These display devices are applied to various electronic devices such as a smartphone and a tablet PC.

The display device includes various electrodes, various organic or inorganic layers and various elements that display actual images. In such a display device, cracks occur due to external impact. If moisture from the outside penetrates into the display device through such cracks, there is a problem of electrodes being corroded or the organic light emitting layer being deteriorated.

### BRIEF SUMMARY

The present disclosure is directed to a display device and a method of fabricating the same that substantially obviate one or more of the problems associated with the limitations and disadvantages of the related conventional art.

One of the objects of the present disclosure is to provide a display device and a method of fabricating the same capable of reducing or preventing defects occurred from a static electricity in the process of forming a crack detection line.

Additional features and advantages of the present disclosure are set forth in the description which follows, and will be apparent from the description, or evident by practice of the present disclosure. The objectives and other advantages of the present disclosure are realized and attained by the features described herein as well as in the appended drawings.

To achieve these and other advantages in accordance with the purpose of the embodiments of the present disclosure, as described herein, an aspect of the present disclosure is a display device comprising a substrate including a display area and a non-display area outside the display area; a light emitting element in a pixel in the display area; a trimming hole in an edge of the non-display area; a crack detection line disposed between the trimming hole and the display area and surrounding the display area; and a bridge pattern in the trimming hole.

Another aspect of the present disclosure is a method of fabricating a display device comprising forming a buffer layer on the substrate including a display area and a non-display area; forming a semiconductor layer on the buffer layer and in the display area; forming a gate insulating layer on the buffer layer to cover the semiconductor layer; forming a trimming hole along a periphery of the display area by etching the buffer layer and the gate insulating layer; forming a metal layer on the gate insulating layer and in the trimming hole; forming a first photoresist pattern on the metal layer and corresponding to the display area, a second photoresist pattern on the metal layer and corresponding to the non-display area and a third photoresist pattern on the metal layer and corresponding to the trimming hole; patterning the metal layer using the first to third photoresist patterns to form a gate electrode in the display area, a crack detection line in the non-display area and a bridge pattern in the trimming hole; forming an interlayer insulating layer on the gate electrode and the crack detection line; forming a source electrode and a drain electrode on the interlayer insulating layer and in the display area; forming a light emitting element over the drain electrode; cutting and trimming the substrate along the trimming hole.

It is to be understood that both the foregoing general description and the following detailed description are exemplary and explanatory and are intended to further explain the present disclosure as claimed.

### BRIEF DESCRIPTION OF THE SEVERAL VIEWS OF THE DRAWINGS

The accompanying drawings, which are included to provide a further understanding of the present disclosure and are incorporated in and constitute a part of this specification, illustrate embodiments of the present disclosure and together with the description serve to explain the principles of the present disclosure.

FIG. 1 is a schematic block diagram showing a display device according to an embodiment of the present disclosure.

FIG. 2 is a schematic block diagram showing a subpixel of a display device according to an embodiment of the present disclosure.

FIG. 3 is a circuit diagram of a subpixel of a display device according to an embodiment of the present disclosure.

FIG. 4 is a schematic plan view of a display device according to an embodiment of the present disclosure.

FIG. 5 is an enlarged view of an “A” region in FIG. 4.

FIG. 6 is a cross-sectional view taken along the line I-I′ in FIG. 4.

FIG. 7 is an enlarged cross-sectional view of a “B” region in FIG. 6.

FIGS. 8A to 8F are schematic cross-sectional views showing a process of fabricating a display device according to an embodiment of the present disclosure.

FIGS. 9A and 9B are views showing loss of a photoresist pattern for forming a crack detection line when a photoresist pattern is not formed in a trimming hole.

FIG. 10 is s schematic plane view of a portion of a display device according to another embodiment of the present disclosure.

### DETAILED DESCRIPTION

Reference will now be made in detail to aspects of the present disclosure, examples of which may be illustrated in the accompanying drawings. In the following description, when a detailed description of well-known functions or configurations related to this document is determined to unnecessarily cloud a gist of the disclosure concept, the detailed description thereof will be omitted. The progression of processing steps and/or operations described is a non-limiting example. The sequence of steps and/or operations is not limited to that set forth herein and may be changed to occur in an order that is different from an order described herein, with the exception of steps and/or operations necessarily occurring in a particular order. In one or more examples, two operations in succession may be performed substantially concurrently, or the two operations may be performed in a reverse order or in a different order depending on a function or operation involved.

Like reference numerals designate like elements throughout. Names of the respective elements used in the following explanations are selected only for convenience of writing the specification and may be thus different from those used in actual products.

Advantages and features of the present disclosure and methods of achieving them will be apparent with reference to the aspects described below in detail with the accompanying drawings. However, the present disclosure is not limited to the aspects disclosed below, but can be realized in a variety of different forms, and only these aspects allow the disclosure of the present disclosure to be complete. The present disclosure is provided to fully inform the scope of the disclosure to the skilled in the art of the present disclosure.

The shapes, sizes, proportions, angles, numbers, and the like disclosed in the drawings for explaining the aspects of the present disclosure are illustrative, and the present disclosure is not limited to the illustrated matters. The same reference numerals refer to the same elements throughout the specification. In addition, in describing the present disclosure, if it is determined that a detailed description of the related known technology unnecessarily obscure the subject matter of the present disclosure, the detailed description thereof can be omitted. When ‘comprising’, ‘including’, ‘having’, ‘consisting’, and the like are used in this specification, other parts may be added unless terms such as ‘only’, ‘merely’, or the like are used. When a component is expressed in the singular, cases including the plural are included unless specific statement is described.

The expression “at least one of a, b, and c” described throughout the specification can encompass ‘a alone’, ‘b alone’, ‘c alone’, ‘a and b’, ‘a and c’, ‘b and c’, or ‘all of a, b, and c’. The advantages and features of the present disclosure, and the methods for achieving them, will become apparent by referring to the embodiments described in detail below together with the accompanying drawings.

In construing an element, the element is construed as including an error or tolerance range although there is no explicit description of such an error or tolerance range.

In describing a position relationship, for example, when a position relation between two parts is described as, for example, “on,” “over,” “under,” and “next,” one or more other parts may be disposed between the two parts unless a more limiting term, such as “just” or “direct(ly)” is used.

In describing a time relationship, for example, when the temporal order is described as, for example, “after,” “subsequent,” “next,” and “before,” a case that is not continuous may be included unless a more limiting term, such as “just,” “immediate(ly),” or “direct(ly)” is used.

The area, length, or thickness of each component described in the specification is illustrated for convenience of explanation, and the present disclosure is not necessarily limited to the area and thickness of the illustrated component.

It will be understood that, although the terms “first,” “second,” etc., may be used herein to describe various elements, these elements should not be limited by these terms. These terms are only used to distinguish one element from another. For example, a first element could be termed a second element, and, similarly, a second element could be termed a first element, without departing from the scope of the present disclosure.

Features of various aspects of the present disclosure may be partially or overall coupled to or combined with each other, and may be variously inter-operated with each other and driven technically as those skilled in the art can sufficiently understand. The aspects of the present disclosure may be carried out independently from each other, or may be carried out together in co-dependent relationship.

In the present disclosure, the “display device” may include a narrowly defined display device such as a display module including a display panel and a driving unit for driving the display panel. In addition, the “display device” may also include a set electronic device or a set apparatus such as a notebook computer, a television, a computer monitor, an automotive display, an equipment display, a smart phone, wearable devices such as smart watches, portable multimedia players (PMP), personal digital assistants (PDA), an electronic pad, or the like, being a complete product (or a final product) including a display module.

Accordingly, the display device in the present disclosure may include a display device in the narrow sense, such as a display module, and a set device, which is an application product or final consumer device including the display module.

Reference will now be made in detail to some of the examples and preferred embodiments, which are illustrated in the accompanying drawings.

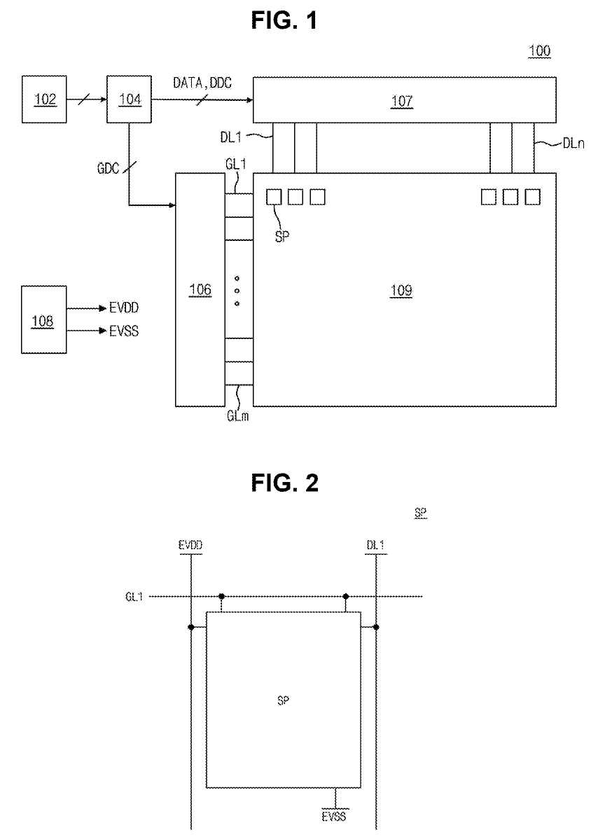

FIG. 1 is a schematic block diagram showing a display device according to an embodiment of the present disclosure, and FIG. 2 is a schematic block diagram showing a subpixel of a display device according to an embodiment of the present disclosure.

As shown in FIG. 1, a display device 100 of the present disclosure includes an image processing unit 102, a timing control unit 104, a gate driving unit 106, a data driving unit 107, a power supply unit 108 and a display panel 109.

The image processing unit 102 outputs an image data supplied from the outside and a driving signal for driving various elements. For example, the driving signal output from the image processing unit 102 may include a data enable signal, a vertical synchronization signal, a horizontal synchronization signal, and a clock signal.

The timing control unit 104 receives the image data and the driving signal from the image processing unit 102. The timing control unit 104 generates and outputs a gate timing control signal GDC for controlling the operation timing of the gate driving unit 106 and a data timing control signal DDC for controlling the operation timing of the data driving unit 107 based on the driving signal input from the image processing unit 102.

The gate driving unit 106 responds to the gate timing control signal GDC supplied from the timing control unit 104 and outputs a scan signal to the display panel 109. The gate driving unit 106 outputs the scan signal through a plurality of gate lines GL1 to GLm. In this case, the gate driving unit 106 may be formed in the form of an IC (integrated circuit), but it is not limited thereto. The gate driving unit 106 includes various gate driving circuits, and the gate driving circuits may be formed directly on the substrate of the display panel 109. In this case, the gate driving unit 106 may be a GIP (Gate-In-Panel).

The data driving unit 107 responds to the data timing control signal DDC input from the timing control unit 104 and outputs the data voltage to the display panel 109. The data driving unit 107 samples and latches the digital data signal DATA supplied from the timing control unit 104. The data driving unit 107 converts the digital data signal DATA into an analog data voltage based on the gamma voltage. The data driving unit 107 outputs the data voltage through a plurality of data lines DL1 to DLn. In this case, the data driving unit 107 may be formed in the form of an IC, but it is not limited thereto.

The power supply unit 108 outputs a high-potential voltage VDD and a low-potential voltage VSS and supplies the high-potential voltage VDD and the low-potential voltage VSS to the display panel 109. The high-potential voltage VDD is supplied to the display panel 109 through a first power line EVDD, and the low-potential voltage VSS is supplied to the display panel 109 through a second power line EVSS. In this case, the voltage output from the power supply unit 108 may be output to the gate driving unit 106 or the data driving unit 107.

The display panel 109 displays an image in response to the scan signal from the gate driving unit 106, the data voltage from the data driving unit 107 and the voltage from the power supply unit 108.

The display panel 109 includes a plurality of subpixels SP and displays an actual image. The subpixels SP may include a red subpixel, a green subpixel and a blue sub-pixel. The subpixels SP may further include a white subpixel. The white, red, green and blue (W, R, G, B) subpixels SP may have the same area. Alternatively, the white, red, green and blue (W, R, G, B) subpixels SP may have different areas.

As shown in FIG. 2, one subpixel SP can be connected to a gate line GL1, a data line DL1, a first power line EVDD and a second power line EVSS. The subpixel SP can include a plurality of thin film transistors and a storage capacitor depending on the configuration of the pixel circuit. For example, the subpixel SP may include two transistors and one capacitor (e.g., a 2T1C structure). Alternatively, the subpixel SP may have one structure of 3T1C, 4T1C, 5T1C, 6T1C, 7T1C, 3T2C, 4T2C, 5T2C, 6T2C, 7T2C and 8T2C.

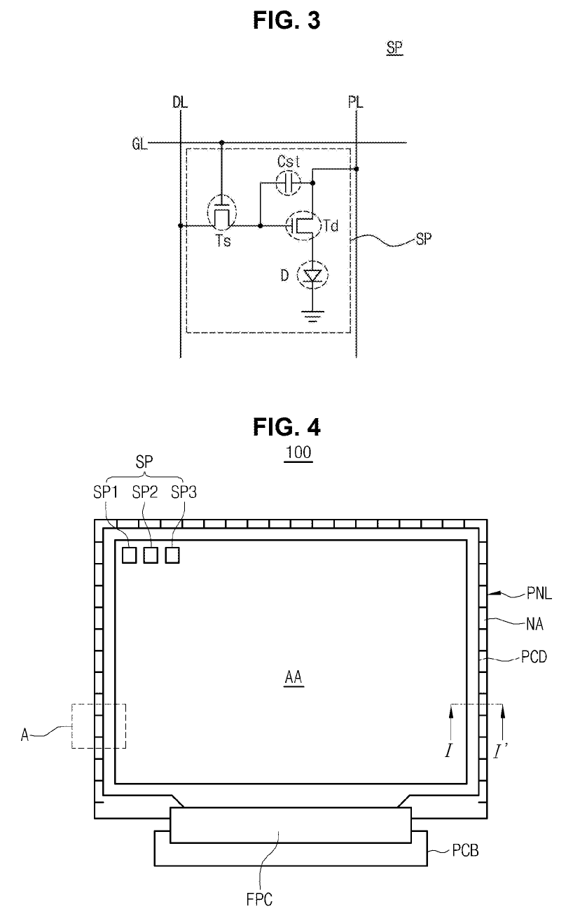

FIG. 3 is a circuit diagram of a subpixel of a display device according to an embodiment of the present disclosure.

As shown in FIG. 3, the display device includes a gate line GL, a data line DL and a power line PL. The gate line GL crosses the data line DL and the power line PL to define the subpixel SP. A switching transistor Ts, a driving transistor Td, a storage capacitor Cst and a light emitting element D are disposed in the subpixel SP.

The switching transistor Ts is connected to the gate line GL and the data line DL, and the driving transistor Td and the storage capacitor Cst are connected to the switching transistor Ts and the power line PL. The light emitting element D is connected to the driving transistor Td.

In the organic light emitting display device, when the switching transistor Ts is turned on by a gate signal applied through the gate line GL, a data signal from the data line DL is applied to the gate electrode of the driving transistor Td and an electrode of the storage capacitor Cst.

When the driving transistor Td is turned on by the data signal, an electric current is supplied to the light emitting element D from the power line PL. As a result, the light emitting element D emits light. In this case, when the driving transistor Td is turned on, a level of an electric current applied from the power line PL to the light emitting element D is determined such that the light emitting element D can produce a gray scale.

The storage capacitor Cst serves to maintain the voltage of the gate electrode of the driving transistor Td when the switching transistor Ts is turned off.

Accordingly, even if the switching transistor (e.g., thin film transistor (TFT)) Ts is turned off, a level of an electric current applied from the power line PL to the light emitting element D is maintained to next frame.

In FIG. 3, the subpixel SP includes two transistors Td and Ts and one storage capacitor Cst. Alternatively, the subpixel SP may include three or more transistors and two or more storage capacitors.

FIG. 4 is a schematic plan view of a display device according to an embodiment of the present disclosure.

As shown in FIG. 4, the display device 100 of the present disclosure includes a display panel PNL, a flexible printed circuit board (e.g., a flexible printed circuit) FPC and a printed circuit board PCB. The display panel PNL includes a display area AA for displaying an image and a non-display area NA outside the display area AA.

A subpixel SP including a plurality of subpixels SP1, SP2 and SP3 is disposed in the display area AA. The subpixels SP1, SP2 and SP3 may include a red subpixel R, a green subpixel G and a blue subpixel B. In addition, the subpixel SP may further include a white subpixel W.

A plurality of gate lines and a plurality of data lines are disposed in the display area AA, and the subpixel SP is disposed at a crossing portion of the gate and data lines. In each of the subpixels SP1, SP2 and SP3, a transistor as a switching element and/or a driving element and a display element are disposed.

The display element may include various display elements. For example, the display element may be an organic light emitting display element (or an organic electroluminescent display element), a liquid crystal display element, a quantum-dot display element, an micro-LED display element or a mini-LED display element.

A gate driving unit (e.g., gate driving unit 106 in FIG. 1) and a data driving unit (e.g., data driving unit 107 in FIG. 1) for applying a signal to the subpixels SP1, SP2 and SP3 may be disposed in the non-display area NA. The gate driving unit provides a scan signal (e.g., a gate signal) to the subpixel through the gate line, and the data driving unit provides an image signal (e.g., a data signal) to the subpixel through the data line. The gate driving unit may be a gate in panel (GIP) circuit to be formed in a non-display area NA of a substrate.

An end of the flexible printed circuit board FPC is attached to an end of the non-display area NA at a bottom side of the display area AA, and the printed circuit board PCB is attached to the other end of the flexible printed circuit board FPC. The data driving unit and a plurality of signal lines may be disposed in the flexible printed circuit board FPC, and a timing control unit and a power supply unit may be disposed in the printed circuit board PCB. In this case, the gate driving unit may be directly disposed on the display panel PNL.

The control signal and the voltage from the timing control unit and the power supply unit in the printed circuit board PCB may be provided to the gate driving unit and the data driving unit through the signal lines.

A crack detection line PCD is disposed in a periphery of the display area AA of the display panel PNL. The crack detection line PCD may surround three sides of the display area AA. For example, the crack detection line PCD may have a “U” shape or a picture frame shape with an opened one side.

The crack detection line PCD is electrically connected to the signal line of the flexible printed circuit board FPC. A resistance

The flexible printed circuit board FPC or the printed circuit board PCB is provided with a resistance measuring unit to measure the resistance value of the crack detection line PCD. If the measured resistance value is detected as infinity, it is determined that a crack has occurs in the crack detection line PCD and the crack has propagated to or has approached the display area AA. If the output resistance value is detected as a set resistance value less than infinity, it is determined that no crack occurs in the crack detection line PCD.

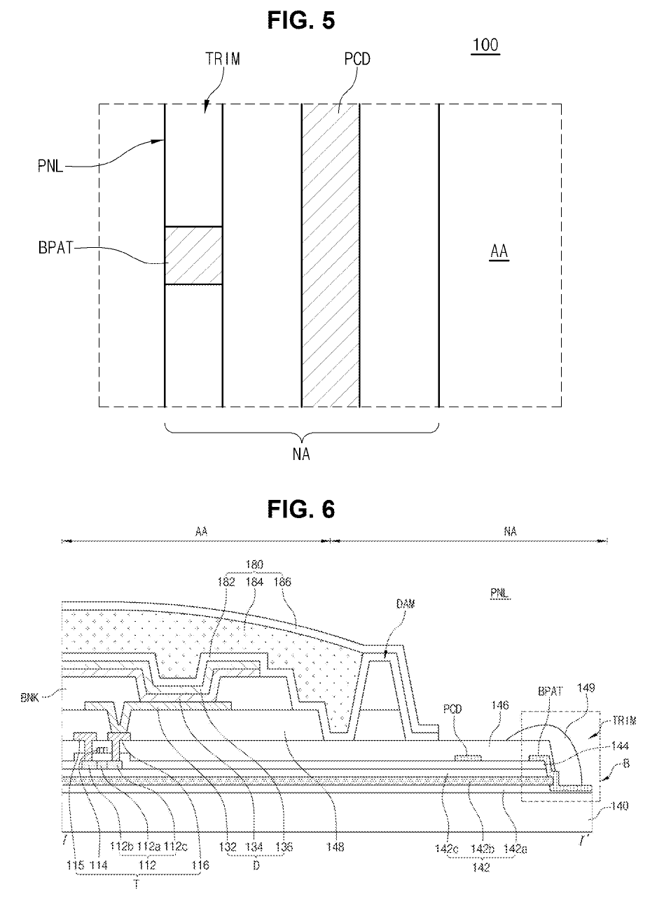

FIG. 5 is an enlarged view of an “A” region in FIG. 4. As shown in FIG. 5, a trimming hole TRIM is formed on an outer edge of the non-display area NA of the display panel PNL. The trimming hole TRIM is used to separate a mother substrate, on which a plurality of display panels PNL are formed. The mother substrate is cut into at least one display panel PNL.

When manufacturing an odd-shaped display device such as a clock display apparatus or a vehicle display apparatus, the display panels are formed on a rectangular mother substrate, and then a cutting and trimming process is performed to manufacture a display device of a desired shape. The trimming hole TRIM may be formed for the trimming process of the odd-shaped display device.

The trimming hole TRIM can be formed by removing a plurality of insulating layers formed in the display panel PNL.

The trimming hole TRIM is formed with a width of a set length from the outer edge of the non-display area NA toward the display area AA. The trimming hole TRIM will be explained in detail later.

The crack detection line PCD is disposed between the trimming hole TRIM and the display area AA. The crack detection line PCD is disposed to be spaced apart from the trimming hole TRIM by a pre-determined distance. Since the trimming hole TRIM is formed along the entire perimeter of the display panel PNL and the crack detection line PCD is disposed along at least three sides of the display panel PNL, the trimming hole TRIM and the crack detection line PCD may be disposed to be adjacent to each other along at least three sides of the display panel PNL.

A bridge pattern BPAT is formed in the trimming hole TRIM. The bridge pattern BPAT may be formed only within the trimming hole TRIM, but it is not limited thereto. At least a portion of the bridge pattern BPAT can be formed within the trimming hole TRIM. For example, a portion of the bridge pattern BPAT (which may be referred to as the first bridge pattern portion) can be formed within the trimming hole TRIM, while another portion of the bridge pattern BPAT (which may be referred to as the second bridge pattern portion) can extend to the outside of the trimming hole TRIM. The first bridge pattern portion may continuously cover the inner wall of the trimming hole TRIM and connect with the second bridge pattern portion. The second bridge pattern portion can increase the contact area between the bridge pattern BPAT and the attached layer on the substrate, thereby increasing the stability of the formed structure and making it more conducive to subsequent cutting and trimming processes.

The bridge pattern BPAT may extend toward the display area AA by a pre-determined distance. The bridge pattern BPAT is arranged to be spaced apart from the crack detection line PCD by a pre-determined distance.

The bridge pattern BPAT may have a band-shaped pattern with a pre-determined width. A plurality of bridge patterns BPAT may be disposed along the perimeter of the display panel PNL at a pre-determined interval. For example, the bridge pattern BPAT may include a plurality of patterns disposed along the trimming hole TRIM and spaced apart from each other. In addition, the bridge pattern BPAT as an integrated-body may be disposed continuously along the perimeter of the display panel PNL. For example, the bridge pattern BPAT as an integrated-body may be disposed along the trimming hole TRIM.

FIG. 6 is a view illustrating a structure of a display panel of the present disclosure and is a cross-sectional view taken along the line I-I′ in FIG. 4.

For convenience of explanation, FIG. 6 shows one subpixel of the display area AA and the non-display area NA.

A substrate 140 includes a display area AA and a non-display area NA. The substrate 140 may be formed of a hard material, e.g., glass, or a plastic material having flexibility.

For example, the substrate 140 may be formed of at least one of polyimide, polymethylmethacrylate, polyethylene terephthalate, polyethersulfone and polycarbonate, but it is not limited thereto.

In an embodiment of the present disclosure, the substrate 140 may include a plurality of polyimide layers and an inorganic layer between the polyimide layers, but it is not limited thereto.

A buffer layer 142 is disposed on the substrate 140. The buffer layer 142 may be disposed on an entire surface of the substrate 140 to enhance an adhesion between the substrate 140 and layers formed on the substrate 140 and to block impurity, e.g., alkaline components, from the substrate 140. In addition, the buffer layer 142 can delay the diffusion of moisture or oxygen that has penetrated into the substrate 140.

The buffer layer 142 may include a first buffer layer 142a, a second buffer layer 142b on the first buffer layer 142a and a third buffer layer 142c on the second buffer layer 142b. For example, each of the first and third buffer layers 142a and 142c may be formed of silicon oxide (SiOx), and the second buffer layer 142b may be formed of silicon nitride (SiNx). However, it is not limited thereto.

A thin film transistor (TFT) T is disposed on the buffer layer 142 in the display area AA.

For convenience of explanation, FIG. 6 shows a driving TFT (e.g., the driving transistor Td in FIG. 3). Other TFTs such as a switching TFT (e.g., the switching transistor Ts in FIG. 3) may be further disposed on the buffer layer 142 and in the display area AA. The TFT T in FIG. 6 has a top-gate structure. Alternatively, the TFT T may have a bottom-gate structure.

The TFT T includes a semiconductor layer 112 on the buffer layer 142, a gate insulating layer 144 on the semiconductor layer 112, a gate electrode 114 on the gate insulating layer 144, an interlayer insulating layer 146 on the gate electrode 114 and source and drain electrodes 115 and 116 on the interlayer insulating layer 146.

The semiconductor layer 112 may be formed of a poly-crystalline semiconductor material. For example, the poly-crystalline semiconductor material may be a low temperature poly silicon (LTPS), but it is not limited thereto.

In an embodiment of the present disclosure, the semiconductor layer 112 may be formed of an oxide semiconductor material. For example, the semiconductor layer 112 may be formed of one of indium-gallium-zinc-oxide (IGZO), indium-zinc-oxide (IZO), indium-gallium-tin-oxide (IGTO) and indium-gallium-oxide (IGO), but it is not limited thereto. The semiconductor layer 112 may include a channel region 112a, a source region 112b at one side of the channel region 112a and a drain region 112c at the other side of the channel region 112a.

The gate insulating layer 144 may cover the display area AA and the non-display area NA. The gate insulating layer 144 may only cover display area AA. The gate insulating layer 144 may be formed of an inorganic insulating material, e.g., silicon oxide or silicon nitride, and may have a single-layered structure or a multi-layered structure. However, it is not limited thereto.

The interlayer insulating layer 146 may cover the display area AA and the non-display area NA. The interlayer insulating layer 146 may only cover display area AA. The interlayer insulating layer 146 may be formed of an organic insulating material, e.g., photo-acryl, or an inorganic insulating material, e.g., silicon oxide or silicon nitride, and may have a single-layered structure or a multi-layered structure. For example, the interlayer insulating layer 146 may have a multi-layered structure including an organic insulating material layer and an inorganic insulating material layer. However, it is not limited thereto.

Each of the gate electrode 114, the source electrode 115 and the drain electrode 116 may be formed of a conductive material, e.g., molybdenum (Mo), aluminum (Al), chromium (Cr), gold (Au), titanium (Ti), nickel (Ni), neodymium (Nd) or copper (Cu), and may have a single-layered structure or a multi-layered structure. However, it is not limited thereto. The source and drain electrodes 115 and 116 may be connected to (e.g., contact) the source and drain regions 112b and 112c of the semiconductor layer 112 through a contact hole in the gate insulating layer 144 and the interlayer insulating layer 146, respectively.

A bottom shield metal layer may be disposed between the semiconductor layer 112 and the substrate 140. The back channel phenomenon caused by charges trapped in the substrate 140 can be reduced or minimized by the bottom shield metal layer so that afterimages or performance degradation of the TFT T can be reduced or prevented. The bottom shield metal layer may be formed of a conductive material, e.g., titanium (Ti), molybdenum (Mo) or their alloys, and may have a single-layered structure or a multi-layered structure. However, it is not limited thereto.

A planarization layer 148 is formed over the substrate 140 including the TFT T. The planarization layer 148 may be formed of an organic insulating material, e.g., photo-acryl, but it is not limited. The planarization layer 148 may have a multi-layered structure including an inorganic insulating layer and an organic insulating layer or a multi-layered structure including two or more organic insulating layers.

A first electrode 132 is disposed on the planarization layer 148 and is connected to the drain electrode 116 of the TFT T through a contact hole in the planarization layer 148. The first electrode 132 may be formed of at least one of aluminum (Al), gold (Au), molybdenum (Mo), tungsten (W), chromium (Cr) and their alloys. Alternatively, the first electrode 132 may include a transparent conductive oxide material layer formed of indium-tin-oxide (ITO) or indium-zinc-oxide (IZO).

In a top-emission type display device 100, the first electrode 132 may include an opaque (or reflective) conductive material layer with the transparent conductive oxide material layer. In a bottom-emission type display device 100, the first electrode 132 may include a transparent conductive oxide material layer without an opaque conductive material layer.

A bank BNK is disposed at a boundary of each subpixel and on the planarization layer 148. The bank BNK may be a partition wall for defining a subpixel. The bank BNK surrounds the subpixel so that a color mixture in adjacent subpixels can be reduced or prevented.

The bank BNK may be formed of an inorganic insulating material, e.g., silicon nitride (SiNx) or silicon oxide (SiOx), an organic insulating material, e.g., benzocyclobutene (BCB), acryl resin, epoxy resin, phenolic resin, polyamide resin or polyimide resin, or a photo-sensitive material including a black pigment. However, it is not limited thereto.

A light emitting layer 134 may be formed on an upper surface of the first electrode 132, an inclined surface of the bank BNK and a part of an upper surface of the bank BNK in the display area AA. The light emitting layer 134 may extend into at least a portion of the non-display area NA.

The light emitting layer 134 may include a red emitting layer, a green emitting layer and a blue emitting layer. The red emitting layer is disposed in the red subpixel and provides red emission, the green emitting layer is disposed in the green subpixel and provides green emission, and the blue emitting layer is disposed in the blue subpixel and provides blue emission. For example, the light emitting layer 134 may include an organic light emitting layer or an inorganic light emitting layer, e.g., a nano-sized material layer, a quantum-dot layer, a micro-LED light emitting layer or a mini-LED light emitting layer. However, it is not limited thereto.

The light emitting layer 134 may include an emitting material layer. In addition, the light emitting layer 134 may further include at least one of a hole injection layer for injecting a hole, an electron injection layer for injecting an electron, a hole transporting layer for transporting a hole, an electron transporting layer for transporting an electron, a hole blocking layer and an electron blocking layer. However, it is not limited thereto.

A second electrode 136 is disposed on the light emitting layer 134. The second electrode 136 may be formed of a metal or an alloy and may have a single-layered structure or a multi-layered structure. In an embodiment of the present disclosure, the second electrode 136 may be formed of a transparent conductive oxide material. However, it is not limited thereto.

In a top-emission type display device 100, the second electrode 136 may have a thin profile to have a transparent or semi-transparent property. For example, the second electrode 136 may be formed of at least one of alloys of LiF/Al, CsF/Al, Mg:Ag, Ca/Ag, Ca:Ag, LiF/Mg:Ag, LiF/Ca/Ag or LiF/Ca:Ag.

In a bottom-emission type display device 100, the second electrode 136 may be formed of an opaque conductive material to be a reflective electrode. For example, the second electrode 136 may be formed of at least one of Ag, Al, Au, Mo, W, Cr or their alloys.

The first electrode 132, the light emitting layer 134 and the second electrode 136 constitute a light emitting element D. The light emitting element D may be an organic light emitting element, where the light emitting layer 134 is an organic light emitting layer, or an inorganic light emitting element, where the light emitting layer 134 is an inorganic light emitting layer. The light emitting element D may be a light emitting diode.

The light emitting element D may have a tandem structure. In the tandem structure light emitting element D, the light emitting layer 134 includes a plurality of emitting material layers and one or more charge generation layer between adjacent emitting material layers. The charge generation layer controls a charge balance in the plurality of emitting material layers and may have a multi-layered structure including an n-type charge generation layer and a p-type charge generation layer. The charge generation layer may be doped with an alkali metal, e.g., Li, Na, K , Cs or the like, and an alkali earth metal, e.g., Mg, Sr, Ba, Ra or the like. However, it is not limited thereto.

An encapsulation layer 180 is disposed on the display area AA and the non-display area NA to cover or seal the light emitting element D. When the light emitting element D is exposed to oxygen and/or moisture, a pixel shrinkage phenomenon, in which an emission area is reduced, or a defect such as dark spots appears within the emission area may occur. In addition, moisture or oxygen may oxidize the electrodes made of metal. The encapsulation layer 180 blocks the penetration of moisture and/or oxygen from the outside so that defects in the light emitting element D and various electrodes can be reduced or prevented.

The encapsulation layer 180 may include a first encapsulation layer 182, a second encapsulation layer 184 and a third encapsulation layer 186. In an embodiment of the present disclosure, the encapsulation layer 180 may have a double-layered structure or a multi-layered structure including four or more layers.

Each of the first and third encapsulation layers 182 and 186 may be formed of an inorganic insulating material, e.g., silicon oxide (SiOx), silicon oxynitride (SiON) or silicon nitride (SiNx), and may have a single-layered structure or a multi-layered structure. Each of the first and third encapsulation layers 182 and 186 may further include an organic insulating material. The second encapsulation layer 184 may be formed of an organic material such as epoxy resin.

A touch element may be disposed. The touch element may be disposed in the display area AA to detect touch input. The touch element may detect external touch information using a user’s finger or a touch pen.

A dam DAM is disposed in the non-display area NA. The organic material forming the second encapsulating layer 184 has fluidity. When the second encapsulating layer 184 is formed, the organic material may flow outward from the outside of the non-display area NA to the outside of the substrate 140 due to the fluidity. The dam DAM is formed to surround the display area AA to confine the organic material flowing outward from the substrate 140 when the second encapsulating layer 184 is formed. As a result, the organic material from flowing outward from the substrate 140 can be reduced or prevented. FIG. 6 show a single dam DAM. Alternatively, a plurality of dams DAM may be arranged.

The dam DAM may have a multi-layered structure. For example, the dam DAM may include a first layer being formed of the same material as the planarization layer 148 and a second layer being formed of the same material as the bank BNK. Alternatively, the dam DAM may have a single-layered structure or a multi-layered structure including three or more layers.

The crack detection line PCD is disposed in the non-display area NA and outside the dam DAM. The crack detection line PCD may be disposed on the gate insulating layer 144, but it is not limited thereto. When the crack detection line PCD is disposed on the gate insulating layer 144 (i.e., disposed at the same layer as the gate electrode 114), the crack detection line PCD may be formed of the same metal as the gate electrode 114 of the TFT T. However, it is not limited thereto.

For example, the crack detection line PCD can be disposed on the interlayer insulating layer 146. In this case, the encapsulating layer 180 can extend to cover and protect the crack detection line PCD, and since the crack detection line PCD is located at the same layer as the source electrode 115 and drain electrode 116 of the TFT T, the crack detection line PCD may be formed of the same metal as the source electrode 115 and drain electrode 116. At this time, the second bridge pattern portion of the bridge pattern BPAT can be located at the same layer as the crack detection line PCD. Therefore, the second bridge pattern portion may be formed on the same layer as the crack detection line PCD and at least one of the gate electrode 114, source electrode 115, and drain electrode 116 of the TFT T. The first bridge pattern portion and the second bridge pattern portion may be formed of the same material as the crack detection line PCD and at least one of the gate electrode 114, source electrode 115, and drain electrode 116 of the TFT T. Thus, the crack detection line PCD and the bridge pattern BPAT may be formed together with the TFT T, thereby reducing or preventing reduction in process efficiency.

The trimming hole TRIM is formed at an edge end of the display device 100. The trimming hole TRIM can be formed by removing at least some layers among the interlayer insulating layer 146, the gate insulating layer 144, and the buffer layer 142. Since the trimming hole TRIM is an area where the display panel PNL is cut and trimmed, a trimming hole of the completed (or final) display panel PNL can have only one half of the original trimming hole TRIM, and the rest of the trimming hole TRIM can be removed by the trimming process.

At least a portion of the bridge pattern BPAT may be formed in the trimming hole TRIM. The bridge pattern BPAT may extend from the trimming hole TRIM to a portion on the gate insulating layer 144 thereby having the second bridge pattern portion located on the gate insulating layer 144 (i.e., at the same layer as the gate electrode 114). The bridge pattern BPAT is arranged to be spaced apart from the crack detection line PCD. The bridge pattern BPAT may be formed of the same metal as the crack detection line PCD or the gate electrode 114, but it is not limited thereto.

A cover layer 149 is formed in the trimming hole TRIM to cover the bridge pattern BPAT. The cover layer 149 may cover a side surface of the interlayer insulating layer 146 and a portion of an upper surface of the interlayer insulating layer 146. The penetration of moisture and/or oxygen into the display panel PNL through the trimming hole TRIM can be reduced or prevented by the cover layer 149. The cover layer 149 may be formed of an organic material or an inorganic material, but it is not limited thereto.

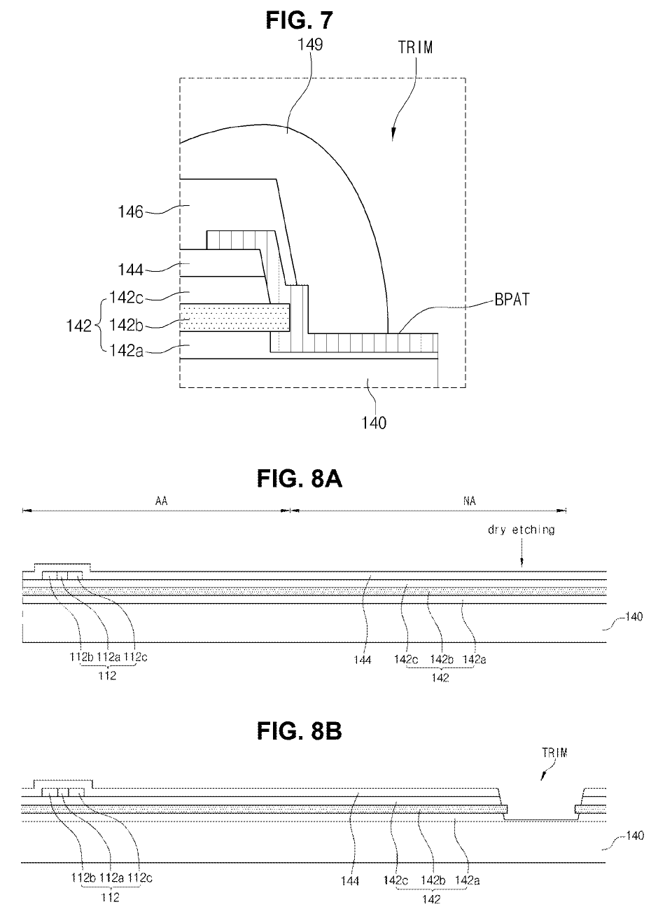

FIG. 7 is an enlarged cross-sectional view of an “B” region in FIG. 6. The trimming hole TRIM is further explained with FIG. 7.

As shown in FIG. 7, the buffer layer 142 on the substrate 140 includes the first to third buffer layers 142a, 142b and 142c. Each of the first and third buffer layers 142a and 142c may be formed of silicon oxide (SiOx), and the second buffer layer 142b may be formed of silicon nitride (SiNx).

The gate insulating layer 144 is disposed on the buffer layer 142, and the interlayer insulating layer 146 is disposed on the gate insulating layer 144. The trimming hole TRIM may be formed by removing the gate insulating layer 144, the interlayer insulating layer 146 and a portion of the buffer layer 142 or the gate insulating layer 144 and a portion of the buffer layer 142. In this case, the first buffer layer 142a disposed on the substrate 140 is partially removed so that a thin first buffer layer 142a remains on the substrate 140 in the trimming hole TRIM. Namely, the first buffer layer 142a has a first thickness in the trimming hole TRIM and a second thickness, which is greater than the first thickness, outside the trimming hole TRIM.

As will be described later, the buffer layer 142, the gate insulating layer 144 or the interlayer insulating layer 146 may be removed by a dry etching process. The first buffer layer 142a and the third buffer layer 142c are formed of silicon oxide and the second buffer layer 142b is formed of silicon nitride. When the buffer layer 142 is etched by the dry etching process, there is a difference in an etching rate between the silicon oxide layer and the silicon nitride layer so that the second buffer layer 142b may protrude from the sidewall of the trimming hole TRIM, i.e., protrude more than the first buffer layer 142a and the third buffer layer 142c. Of course, this disclosure is not limited to the configuration in which the first buffer layer 142a and the third buffer layer 142c are formed of silicon oxide and the second buffer layer 142b is formed of silicon nitride. Under predetermined process conditions, the etching rate of the materials of the first buffer layer 142a and the third buffer layer 142c is greater than the etching rate of the material of the second buffer layer 142b, such that the second buffer layer 142b can protrude from the sidewall of the trimming hole TRIM.

The bridge pattern BPAT is formed in the trimming hole TRIM and on the upper surface of the gate insulating layer 144. The bridge pattern BPAT extends from the outer edge of the display panel PNL to the trimming hole TRIM and the upper surface of the gate insulating layer 144. Since the second buffer layer 142b protrudes from the side surface of the first and third buffer layers 142a and 142c toward the trimming hole TRIM, the bridge pattern BPAT has a step difference in a side surface of the trimming hole TRIM. Since the second buffer layer 142b protrudes from the sidewall of the trimming hole TRIM, a side surface of the second buffer layer 142b (e.g., a side surface of the protruding portion), a portion of a lower surface of the second buffer layer 142b (e.g., a lower surface of the protruding portion) and a portion of an upper surface of the second buffer layer 142b (e.g., an upper surface of the protruding portion) may be covered by the bridge pattern BPAT or contact the bridge pattern BPAT. The buffer layer 142 with such a protruding portion can increase the contact area with the bridge pattern BPAT, thereby increasing the stability of the formed structure and making it more conducive to subsequent cutting and trimming processes.

As described above, since the display device 100 according to the present disclosure includes the crack detection line PCD arranged along the outer perimeter of the non-display area NA, the occurrence of a crack in the non-display area NA can be quickly detected. As a result, when a crack occurs, measures can be taken quickly, and a defect in the display device 100 can be reduced or prevented.

A fabricating method of the display device 100 of the presented disclosure will be described.

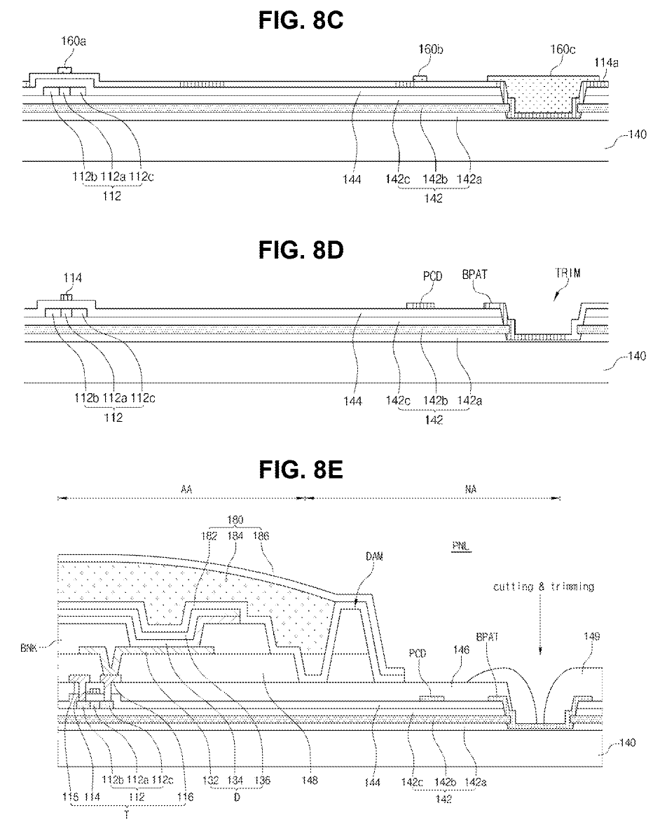

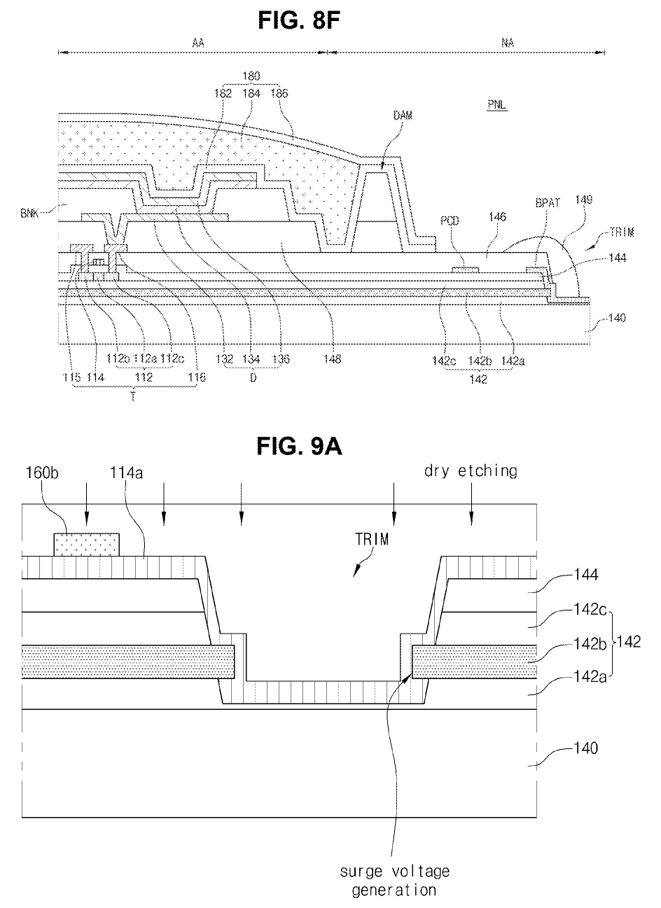

FIGS. 8A to 8F are schematic cross-sectional views showing a process of fabricating a display device according to an embodiment of the present disclosure.

As shown in FIG. 8A, the buffer layer 142 is formed on an entire surface of the first substrate 140 including the display area AA and the non-display area NA. The substrate 140 may be formed of a hard material, e.g., glass, or a plastic material having flexibility, e.g., polyimide, polymethylmethacrylate, polyethylene terephthalate, polyethersulfone or polycarbonate.

The buffer layer 142 may be formed by sequentially depositing the first buffer layer 142a of silicon oxide, the second buffer layer 142b of silicon nitride and the third buffer layer 142c of silicon oxide.

Next, the semiconductor layer 112 is formed on the buffer layer 142 by forming and etching a polysilicon layer or an oxide semiconductor layer, e.g., IGZO, IZO, IGTO or IGO. In addition, impurities may be doped into both ends of the semiconductor layer 112 to form the source region 112b and the drain region 112c at both sides of the channel region 112a.

Next, the gate insulating layer 144 is formed by depositing an inorganic insulating material, e.g., silicon oxide or silicon nitride. The gate insulating layer 144 is disposed in the display area AA and non-display area NA and cover the semiconductor layer 112.

Next, as shown in FIG. 8B, the first to third buffer layers 142a, 142b and 142c and the gate insulating layer 144 are etched using an etching gas to form the trimming hole TRIM in the non-display area NA. In this case, the etching rate of the first and third buffer layers 142a and 142c is different from the etching rate of the second buffer layer 142b so that an end of the second buffer layer 142b may protrude from a side surface of the trimming hole TRIM to an interior (e.g., a center) of the trimming hole TRIM.

Next, as shown in FIG. 8C, a metal layer 114a is formed over an entire surface of the substrate 140 by depositing a metal, e.g., Mo, Al, Cr, Au, Ti, Ni, Nd or Cu, with a sputtering method. Photoresist (PR) is coated and developed to form a first PR pattern 160a on the metal layer 114a in the display area AA and a second PR pattern 160b and a third PR pattern 160c on the metal layer 114a and the non-display area NA. The first PR pattern 160a corresponds to the channel region 112a, the second PR pattern 160b corresponds to the crack detection line PCD (of FIG. 6), and the third PR pattern 160c corresponds to the trimming hole TRIM (of FIG. 8B). The third PR pattern 160c corresponds to and/or covers the metal layer 114a on a bottom of the trimming hole TRIM and a side of the trimming hole TRIM. In other words, the third PR pattern 160c corresponds to and/or covers the metal layer 114a on an upper surface of the first buffer layer 142a and a side surface of the first to third buffer layers 142a to 142c and the gate insulating layer 144.

Next, as shown in FIG. 8D, the metal layer 114a is etched by using the first to third PR patterns 160a, 160b and 160c as an etching mask to form the gate electrode 114, the crack detection line PCD and the bridge pattern BPAT. The gate electrode 114 is disposed over the semiconductor layer 112, and the crack detection line PCD and the bridge pattern BPAT are disposed in the non-display area NA. The bridge pattern BPAT may be disposed in the trimming hole TRIM and a portion of the upper surface of the gate insulating layer 144. Since the first buffer layer 142a is partially removed, the bridge pattern BPAT in the trimming hole TRIM contacts an upper surface of the first buffer layer 142a.

In the present disclosure, the bridge pattern BPAT is formed in the process of forming the gate electrode 114 and the crack detection line PCD for the following reasons.

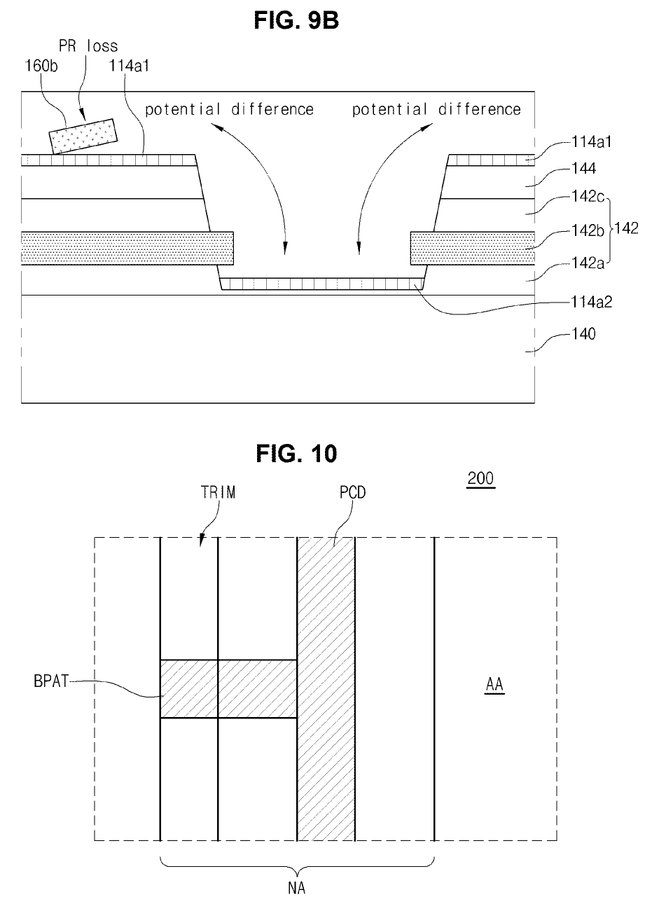

When the metal layer 114a is deposited, a thickness of the metal layer 114a at a side surface (e.g., an inclined surface) in the trimming hole TRIM is smaller than a thickness of the metal layer 114a on an upper surface of the gate insulating layer 144. Accordingly, as shown in FIG. 9A, when the etching process, e.g., a dry-etching process, is performed to the metal layer 114a without the third PR pattern 160c (of FIG. 8C) corresponding to the trimming hole TRIM, the metal layer 114a at the side surface in the trimming hole TRIM is first removed.

Accordingly, as shown in FIG. 9B, during the etching process, the metal layer 114a1 on the gate insulating layer 144 and the metal layer 114a2 on a bottom of the trimming hole TRIM are electrically insulated with the inclined surface of the trimming hole TRIM therebetween.

Since the dry-etching process uses a plasma gas or an reactive gas, a static electricity may be generated during etching. This static electricity generates a potential difference between the metal layer 114a1 on the upper surface of the gate insulating layer 144 and the metal layer 114a2 on the bottom of the trimming hole TRIM, and the potential difference causes an arc discharge between the metal layer 114a1 on the upper surface of the gate insulating layer 144 and the metal layer 114a2 on the bottom of the trimming hole TRIM. The second PR pattern 160b on the metal layer 114a1 may be damaged by this arc discharge. As a result, the second PR pattern 160b may be damaged or lost.

In addition, a surge voltage due to the static electricity during the etching process may be generated in the protruding portion of the second buffer layer 142b, and the second PR pattern 160b may be damaged or lost due to the surge voltage.

There may be a problem in that the crack detection line PCD was damaged or disconnected when forming the crack detection line PCD due to the damage or the loss of the second PR pattern 160b. In other words, there may be problems such as the crack detection line PCD not being formed or having a poor line width.

On the other hand, in the present disclosure, by forming the third PR pattern 160c in the trimming hole TRIM, the metal layer 114a formed on the inclined surface of the trimming hole TRIM is prevented from being etched during the etching process of the metal layer 114a. Accordingly, the metal layer 114a on the upper surface of the gate insulating layer 144 and the metal layer 114a inside the trimming hole TRIM have an electrically connected state during the etching process so that an arc discharge by a static electricity generated during the etching process can be reduced or prevented.

In addition, by blocking the inside of the trimming hole TRIM from the outside by the third PR pattern 160c, it is possible to reduce or prevent the generation of a surge voltage, which is caused by a static electricity generated during the etching process, in the protruding portion of the second buffer layer 142b.

As described above, in the present disclosure, by forming the third PR pattern 160c corresponding to the trimming hole TRIM, a defect in the crack detection line PCD due to a static electricity during the process can be reduced or prevented.

Referring to FIG. 8E, an interlayer insulating layer 146 is formed by depositing an organic insulating material, e.g., photo-acryl, or an inorganic insulating material, e.g., silicon nitride (SiNx) or silicon oxide (SiOx). A metal, e.g., Cr, Mo, Ta, Cu, Ti, Al or Al alloy is deposited on the interlayer insulating layer 146 by a sputtering process and etched to form a source electrode 115 and a drain electrode 116. The source and drain electrodes 115 and 116 respectively ohmic-contact the source and drain regions 112b and 112c of the semiconductor layer 112 through a contact hole in the interlayer insulating layer 146. By the above processes, the TFT T is produced.

Next, a planarization layer 148 in the display area AA and a cover layer 149 in the non-display area NA are formed by depositing an organic insulating material, e.g., photo-acryl, or an inorganic insulating material, e.g., silicon nitride (SiNx) or silicon oxide (SiOx). The planarization layer 148 and the cover layer 149 may be formed by the same process. Namely, the step of forming the planarization layer 148 and the step of forming the cover layer 149 is simultaneously performed. Alternatively, the planarization layer 148 and the cover layer 149 may be formed by different processes. The planarization layer 148 is positioned in the display area AA. The cover layer 149 is positioned in the trimming hole TRIM. For example, the cover layer 149 includes a first cover layer at a first portion of the trimming hole TRIM and a second cover layer at a second portion of the trimming hole TRIM. The first and second cover layers are spaced apart from each other with respect to a center of the trimming hole TRIM.

Next, a first electrode 132 is formed on the planarization layer 148. For example, a transparent conductive oxide material, e.g., ITO or IZO, a metal, e.g., Ag, Au, Mo, W or Cr, and a transparent conductive oxide material, e.g., ITO or IZO, are sequentially stacked and etched to form the first electrode 132 having a triple-layered structure of a transparent conductive layer, a metal layer and a transparent conductive layer. The first electrode 132 is connected to the drain electrode 116 of the TFT T through a contact hole in the planarization layer 148.

Next, at least one material among an inorganic insulating material, e.g., SiNx or SiOx, an organic insulating material, e.g., benzocyclobutene (BCB), an acrylic resin, an epoxy resin, a phenolic resin, a polyamide resin or a polyimide resin, or a photosensitive agent containing a black pigment is deposited on the planarization layer 148 and etched using a dry etching process to form a bank BNK. In addition, a dam DAM including a first layer formed of the same material as the planarization layer 148 and a second layer formed of the same material as the bank BNK is formed in the non-display area NA.

Next, an emitting material is coated to the display area AA and a translucent (e.g., a semi-transparent) alloy, e.g., LiF/Al, CsF/Al, Mg:Ag, Ca/Ag, Ca:Ag, LiF/Mg:Ag, LiF/Ca/Ag or LiF/Ca:Ag, is deposited to form a light emitting layer 134 and a second electrode 136.

Next, an encapsulation layer 180 including a first inorganic layer (e.g., first encapsulation layer 182) formed of an inorganic insulating material, an organic layer (e.g., second encapsulation layer 184) formed of an organic insulating material and an inorganic layer (e.g., third encapsulation layer 186) formed of an inorganic insulating material is formed. The display device 100 (or the light emitting element (e.g., OLED) D) is encapsulated by the encapsulation layer 180.

Next, the substrate 140 is cut and trimmed along the trimming hole TRIM to provide the display device 100 in FIG. 8F.

The cutting of the substrate 140 can be performed using various methods. For example, the substrate 140 can be cut using a mechanical cutting device such as a cutting wheel, or can be cut using a laser. However, it is not limited thereto. When using a laser cutting device, a carbon dioxide laser can be primarily used, but it is not limited thereto.

The trimming of the substrate 140 can also be performed using various methods. For example, the substrate 140 can be trimmed using a laser. The laser may be a Nd-Yag laser, but it is not limited thereto. By cutting and trimming, the outer area of the display area AA is removed around the center of the trimming hole TRIM. As a result, the display device 100 of the desired shape can be provided.

As described above, in the display device of the present disclosure, the trimming hole TRIM is provided in a trimming area, in which the substrate is cut and trimmed, and a PR pattern is formed in the trimming hole in the process of forming the crack detection line PCD. As a result, the crack detection line PCD and the bridge pattern BPAT are maintained at an equal potential so that the damage or the loss of the PR pattern for forming the crack detection line PCD can be reduced or prevented. Accordingly, the defects in the crack detection line PCD due to the damage and/or the loss of the PR pattern can be reduced or prevented.

FIG. 10 is s schematic plane view of a portion of a display device according to another embodiment of the present disclosure.

As shown in FIG. 10, the display device 200 includes a display panel PNL (of FIG. 4) including a display area AA for displaying an image and a non-display area NA outside the display area AA. A trimming hole TRIM is formed on an outer edge of the non-display area NA of the display panel PNL. The trimming hole TRIM is used to separate a mother substrate, on which a plurality of display panels PNL are formed, into a display panel PNL unit or to manufacture a display device of a different shape.

The trimming hole TRIM is formed with a pre-determined width from the outer edge of the non-display area NA toward the display area AA. A crack detection line PCD is disposed between the trimming hole TRIM and the display area AA. The crack detection line PCD is disposed at a pre-determined distance from the trimming hole TRIM. The trimming hole TRIM is formed along the entire perimeter of the display panel PNL, and the crack detection line PCD is arranged along at least three sides of the display panel PNL. Accordingly, the trimming hole TRIM and the crack detection line PCD can be arranged adjacently along at least three sides of the display panel PNL.

A bridge pattern BPAT is formed in the trimming hole TRIM. The bridge pattern BPAT extends from the trimming hole TRIM to the crack detection line PCD and can be electrically connected to the crack detection line PCD. In this case, the crack detection line PCD and the bridge pattern BPAT can be formed integrally.

It will be apparent to those skilled in the art that various modifications and variations can be made in the embodiments of the present disclosure without departing from the technical idea or scope of the present disclosure. Thus, it is intended that the modifications and variations cover this disclosure provided they come within the scope of the appended claims and their equivalents.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device, comprising:
a substrate including a display area and a non-display area outside the display area;
a light emitting element in a pixel in the display area;
a trimming hole in an edge of the non-display area;
a crack detection line disposed between the trimming hole and the display area, the crack detection line surrounding the display area; and
a bridge pattern in at least the trimming hole.

2. The display device according to claim 1, further comprising:
a buffer layer on the substrate; and
a thin film transistor in the pixel and on the buffer layer,
wherein the thin film transistor includes a semiconductor layer on the buffer layer, a gate insulating layer on the semiconductor layer, a gate electrode on the gate insulating layer, an interlayer insulating layer on the gate electrode, and a source electrode and a drain electrode on the interlayer insulating layer.

3. The display device according to claim 2, wherein the crack detection line is the same material and disposed at the same layer in the display device as the gate electrode.

4. The display device according to claim 2, wherein the bridge pattern is the same material and disposed at the same layer in the display device as the gate electrode.

5. The display device according to claim 1, wherein the bridge pattern includes a plurality of patterns disposed along the trimming hole and spaced apart from each other.

6. The display device according to claim 1, wherein the bridge pattern is disposed along the trimming hole as an integrated body.

7. The display device according to claim 2, wherein the bridge pattern extends from the trimming hole onto an upper surface of the gate insulating layer outside the trimming hole.

8. The display device according to claim 7, wherein the bridge pattern is connected to the crack detection line on the gate insulating layer.

9. The display device according to claim 2, wherein the buffer layer includes a first buffer layer on the substrate, a second buffer layer on the first buffer layer and a third buffer layer on the second buffer layer.

10. The display device according to claim 9, wherein the trimming hole extends through the first buffer layer, the second buffer layer, the third buffer layer, and the gate insulating layer, and
wherein the second buffer layer protrudes further from a side surface of the trimming hole than the first buffer layer and the third buffer layer.

11. The display device according to claim 10, wherein a side surface of the second buffer layer, a portion of a lower surface of the second buffer layer and a portion of an upper surface of the second buffer layer are covered by the bridge pattern.

12. The display device according to claim 1, further comprising:
a cover layer in the trimming hole and covering the bridge pattern.

13. The display device according to claim 1, wherein the bridge pattern includes a first bridge pattern portion located in the trimming hole and a second bridge pattern portion located outside the trimming hole.

14. The display device according to claim 1, wherein the first bridge pattern portion continuously covers an inner wall of the trimming hole and is connected to the second bridge pattern portion.

15. A method of fabricating a display device, comprising:
forming a buffer layer on a substrate including a display area and a non-display area;
forming a semiconductor layer on the buffer layer in the display area;
forming a gate insulating layer on the buffer layer, including covering the semiconductor layer;
forming a trimming hole along a periphery of the display area, including etching the buffer layer and the gate insulating layer;
forming a metal layer on the gate insulating layer in the trimming hole;
forming a first photoresist pattern on the metal layer and corresponding to the display area, a second photoresist pattern on the metal layer and corresponding to the non-display area, and a third photoresist pattern on the metal layer and corresponding to the trimming hole;
patterning the metal layer using the first photoresist pattern, the second photoresist pattern, and the third photoresist pattern, including forming a gate electrode in the display area, a crack detection line in the non-display area, and a bridge pattern in the trimming hole;
forming an interlayer insulating layer on the gate electrode and the crack detection line;
forming a source electrode and a drain electrode on the interlayer insulating layer in the display area;
forming a light emitting element over the drain electrode; and
cutting and trimming the substrate along the trimming hole.

16. The method according to claim 15, wherein the step of patterning the metal layer includes etching the metal layer using an etching gas and blocking the etching gas from reaching the trimming hole with the third photoresist pattern.

17. The method according to claim 15, further comprising:
forming a planarization layer on the drain electrode under the light emitting element.

18. The method according to claim 17, further comprising:
forming a cover layer covering the trimming hole.

19. The method according to claim 18, wherein the step of forming the planarization layer and the step of forming the cover layer are simultaneously performed.

20. The method according to claim 15, wherein forming the buffer layer includes forming a first buffer layer on the substrate, forming a second buffer layer on the first buffer layer, and forming a third buffer layer on the second buffer layer,
wherein forming the trimming hole includes forming the trimming hole through the first buffer layer, the second buffer layer, the third buffer layer, and the gate insulating layer, and
wherein forming the trimming hole includes the second buffer layer extending further from a side surface of the trimming hole than the first buffer layer and the third buffer layer.
